(19) United States
(12) Patent Application Publication
(10) Pub. No.: US 2007/0190705 A1
(43) Pub. Date: Aug. 16, 2007

(54) Method for forming poly-silicon thin-film device

(75) Inventors: Fang-Tsun Chu, Taichung County (TW); Yu-Cheng Chen, Taipei County (TW)

Correspondence Address: BIRCH STEWART KOLASCH & BIRCH, PO BOX 747, FALLS CHURCH, VA, 22040-0747, US

(73) Assignee: Industrial Technology Research Institute

(21) Appl. No.: 11/524,440

(22) Filed: Sep. 21, 2006

(30) Foreign Application Priority Data
Feb. 10, 2006 (TW) 095104509

(51) Int. Cl. H01L 21/84

(52) U.S. Cl. 438/151

(57) ABSTRACT

A method for forming a poly-silicon thin-film device, comprising steps of: providing a substrate; forming a poly-silicon film on the substrate, the poly-silicon film comprising a plurality of poly-silicon grains oriented in a grain growth direction; and forming a plurality of thin-film transistors, each of the thin-film transistors including a channel region formed from a portion of the poly-silicon film; wherein at least one channel region has an equivalent parallel channel region with a channel direction parallel to the grain growth direction and an equivalent perpendicular channel region with a channel direction perpendicular to the grain growth direction.

### BACKGROUND OF THE INVENTION

1. Field of the Invention

The present invention generally relates to a method for forming a poly-silicon (p-Si) thin-film device and, more particularly, to a method using a channel region layout design so as to achieve better uniformity in electrical characteristics of thin-film transistors (TFTs) employed in the p-Si thin-film device.

2. Description of the Prior Art

In semiconductor manufacturing, amorphous silicon (a-Si) thin-film transistors (TFTs) are now widely used in the liquid crystal display (LCD) industry because a-Si films can be deposited on a glass substrate at low temperatures. However, the carrier mobility in an a-Si film is much lower than that in a poly-silicon (p-Si) film, so that conventional a-Si TFT-LCDs exhibit a relatively low driving current that limits their applications for LCD devices with high integrated circuits. Accordingly, there have been lots of reports on converting low-temperature deposited a-Si films into p-Si films using laser crystallizaiton.

Grain boundaries in a p-Si film produced by sequential lateral solidification (SLS) exhibit excellent periodicity. FIG. 1A is a conventional system for forming a p-Si film using SLS. The system comprises: a laser generator 11 for generating a laser beam 12 and a mask 13 disposed in a traveling path of the laser beam 12. The mask has a plurality of transparent regions 13a and a plurality of opaque regions 13b. Each of the plurality of transparent regions 13a is a stripe region with a width W. The laser beam 12 passing through the transparent regions 13a irradiates an a-Si film 15 on the substrate 14 in back of the mask 13 so as to melt the a-Si film 15 in the stripe regions 15a with a width W. As the laser beam 12 is removed, the melted a-Si film 15 in the stripe regions 15a starts to solidify and re-crystallize to form laterally grown silicon grains. Primary grain boundaries 16 parallel to a long side of the stripe regions 15a are thus formed at the center of the stripe regions 15a and a p-Si film is formed to have crystal grains with a grain length equal to a half of the width W, as shown in 1B.

In order to enhance the grain length, U.S. Pat. No. 6,908,835 and U.S. Pat. No. 6,726,768 disclose methods for forming a poly-silicon film using SLS with multiple laser irradiations.

However, the p-Si film grown using SLS has crystalline grains oriented towards a certain grain growth direction and grain boundaries that exhibit excellent periodicity. The electrical characteristics of thin-film transistors (TFTs) employing such a p-Si film rely on the number and arrangement of the grain boundaries that the drain-source current flows through in the channel region. The TFTs with different channel region layout designs result in different current flow directions—perpendicular and parallel to the grain growth direction, which makes the TFTs with the same device parameters formed on the same substrate exhibit different electrical characteristics. Such non-uniformity in electrical characteristics is fatal when it comes to a p-Si thin-film device (for example, a liquid crystal display) employing a large number of TFTs with different channel region layout designs.

In order to overcome the aforementioned problem, Jung discloses, in U.S. Pat. No. 6,521,473, a method for forming a liquid crystal display. The method in U.S. Pat. No. 6,521,473 uses a mask 23 (as shown in FIG. 2A) to form a p-Si film 25 (as shown in FIG. 2B) by SLS to have a grain growth direction 45° differing from the grain growth direction of the conventional laterally grown p-Si film. No matter how the channel regions of the transistors 27 are oriented, the current in the channel regions is always 45° differing from the grain growth direction. Therefore, the transistors 27 exhibit uniform electrical characteristics. However, in this method, some part of the a-Si on the substrate cannot be crystallized, resulting in a smaller usable area that decreases the throughput.

Therefore, there exists a need in providing a method for forming a poly-silicon thin-film device using a channel region layout design so as to achieve better uniformity in electrical characteristics of thin-film transistors (TFTs) employed in the p-Si thin-film device.

### SUMMARY OF THE INVENTION

It is a primary object of the present invention to provide a method for forming a poly-silicon thin-film device using a channel region layout design so as to achieve better uniformity in electrical characteristics of thin-film transistors (TFTs) employed in the p-Si thin-film device.

In order to achieve the foregoing object, the present invention provides a method for forming a p-Si thin-film device, the method comprising steps of: providing a substrate; forming a poly-silicon film on the substrate, the poly-silicon film comprising a plurality of poly-silicon grains oriented in a grain growth direction; and forming a plurality of thin-film transistors, each of the thin-film transistors including a channel region formed from a portion of the poly-silicon film; wherein at least one channel region has an equivalent parallel channel region parallel to the grain growth direction and an equivalent perpendicular channel region perpendicular to the grain growth direction.

Preferably, the poly-silicon film has a plurality of primary grain boundaries perpendicular to the grain growth direction and a plurality of secondary grain boundaries parallel to the grain growth direction.

Preferably, the poly-silicon film is formed using sequential lateral solidification (SLS) with at least one laser irradiation.

Preferably, the channel region is L-shaped, multi-L shaped, fan-shaped or donut-shaped.

Preferably, the poly-silicon thin-film device is a liquid crystal display, a driving circuit for a display and a pixel unit for a display.

### BRIEF DESCRIPTION OF THE DRAWINGS

The objects, spirits and advantages of the preferred embodiments of the present invention will be readily understood by the accompanying drawings and detailed descriptions, wherein:

FIG. 1A is a conventional system for forming a p-Si film using sequential lateral solidification (SLS);

FIG. 1B is a top view of a p-Si film formed using the system in FIG. 1A;

FIG. 2A is a top view of a mask used in a SLS process disclosed in U.S. Pat. No. 6,521,473;

FIG. 2B is a top view of a p-Si film formed using the method disclosed in U.S. Pat. No. 6,521,473 and transistors formed thereon;

FIG. 3 is a top view of a transistor layout design used in a method for forming a poly-silicon thin-film device according to a first embodiment of the present invention;

FIG. 4 is a top view of a transistor layout design used in a method for forming a poly-silicon thin-film device according to a second embodiment of the present invention;

FIG. 5 is a top view of a transistor layout design used in a method for forming a poly-silicon thin-film device according to a third embodiment of the present invention; and

FIG. 6 is a top view of a transistor layout design used in a method for forming a poly-silicon thin-film device according to a fourth embodiment of the present invention.

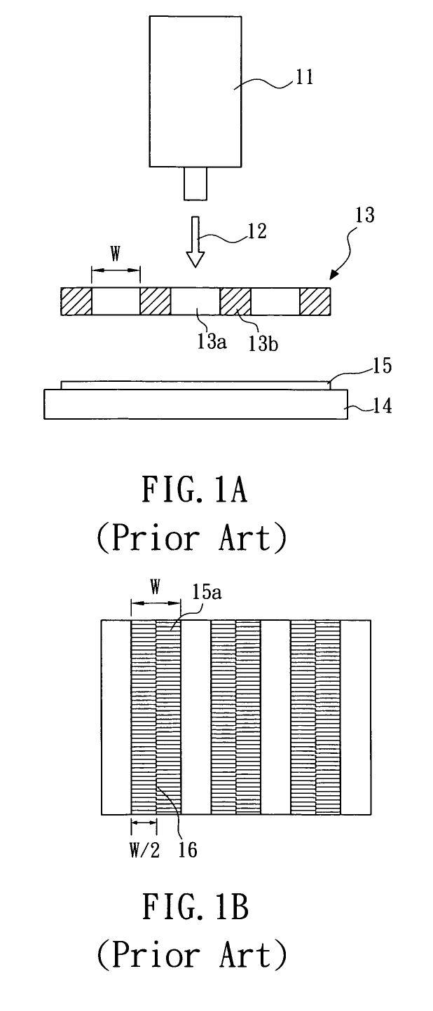

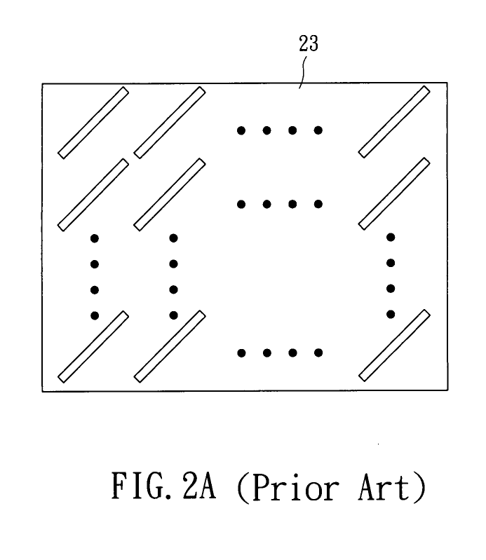

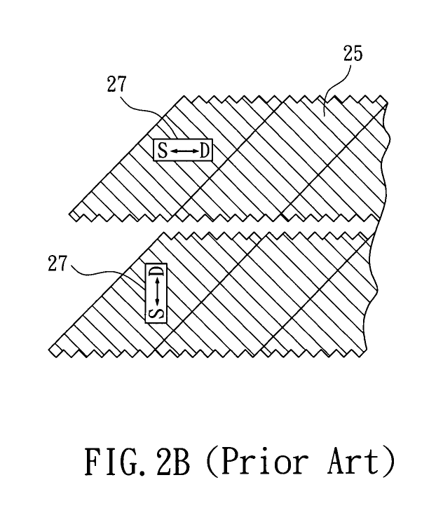

### DETAILED DESCRIPTION OF THE PREFERRED EMBODIMENT

The present invention providing a method for forming a poly-silicon thin-film device can be exemplified by the preferred embodiments as described hereinafter.

In the present invention, a channel region layout design is provided so as to achieve better uniformity in electrical characteristics of thin-film transistors (TFTs) employed in the p-Si thin-film device.

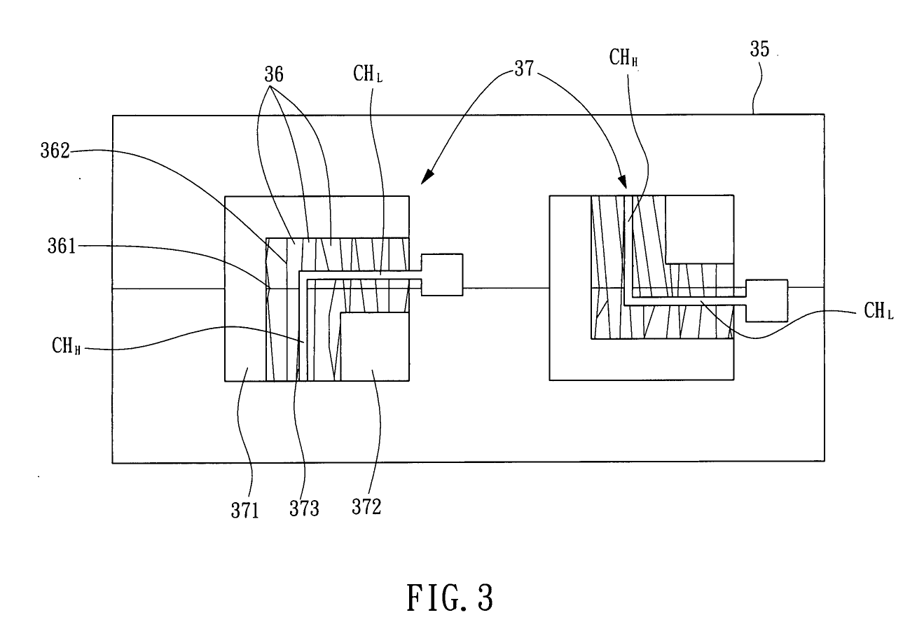

Please refer to FIG. 3, which is a top view of a transistor layout design used in a method for forming a poly-silicon thin-film device according to a first embodiment of the present invention. In the first embodiment, the method comprises steps of: providing a substrate (not shown); forming a poly-silicon film 35 on the substrate, the poly-silicon film comprising a plurality of poly-silicon grains 36 oriented in a grain growth direction; and forming a plurality of thin-film transistors 37, each of the thin-film transistors 37 including a channel region 373 formed from a portion of the poly-silicon film 35; wherein at least one channel region 373 has an equivalent parallel channel region CH_{L} with a channel direction parallel to the grain growth direction and an equivalent perpendicular channel region CH_{H} with a channel direction perpendicular to the grain growth direction.

In the present invention, the poly-silicon film 35 has a plurality of primary grain boundaries 361 perpendicular to the grain growth direction and a plurality of secondary. grain boundaries 362 parallel to the grain growth direction. In the present invention, the poly-silicon film 35 is formed using sequential lateral solidification (SLS) with at least one laser irradiation.

In practical use, the first electrode 371 and the second electrode 372 as shown in FIG. 3 form the drain and source electrodes.

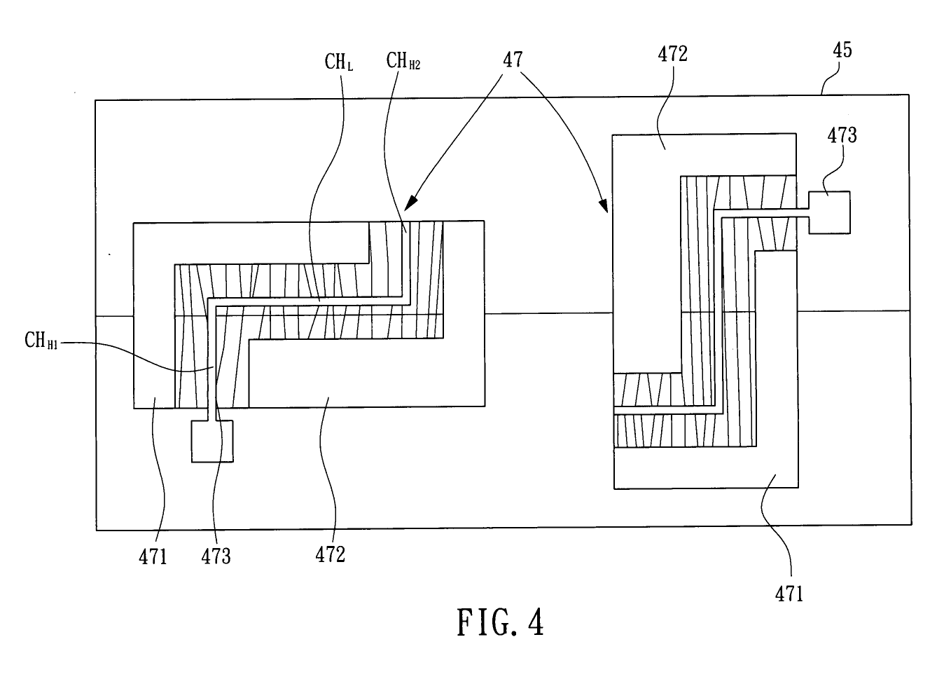

In the present invention, the channel region can be L-shaped (as described in the first embodiment) or multi-L shaped. Please refer to FIG. 4, which is a top view of a transistor layout design used in a method for forming a poly-silicon thin-film device according to a second embodiment of the present invention. In the second embodiment, a plurality of thin-film transistors 47 are formed on a poly-silicon film 45. Each of the thin-film transistors 47 includes a channel region 473 formed from a portion of the poly-silicon film 45. At least one channel region 473 has an equivalent parallel channel region CH_{L} with a channel direction parallel to the grain growth direction, a first equivalent perpendicular channel region CH_{H1} with a channel direction perpendicular to the grain growth direction and a second equivalent perpendicular channel region CH_{H2} with a channel direction perpendicular to the grain growth direction. In practical use, the first electrode 471 and the second electrode 472 as shown in FIG. 4 form the drain and source electrodes.

It is noted that the present invention is exemplified using the first and the second embodiments but not limited thereto. Any person with ordinary skills in the art can make modifications within the scope of the present invention.

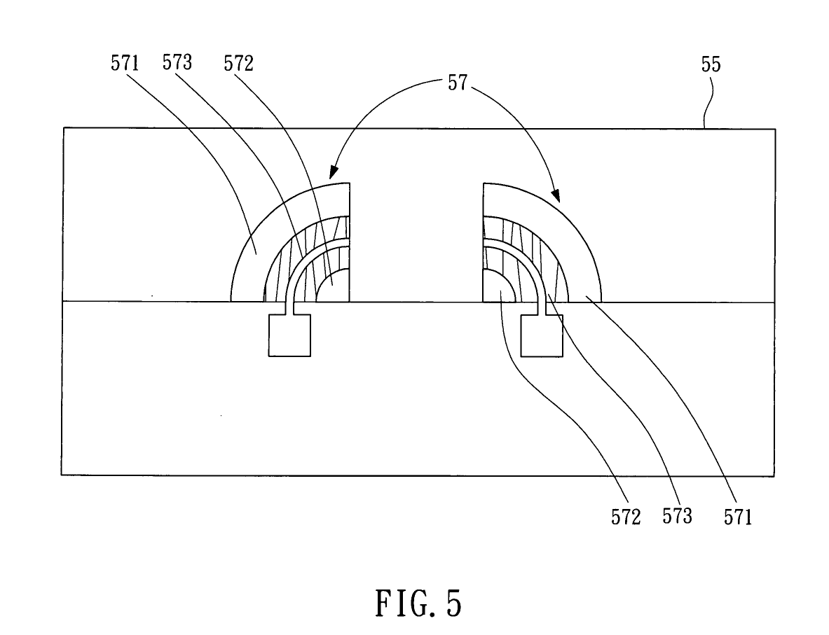

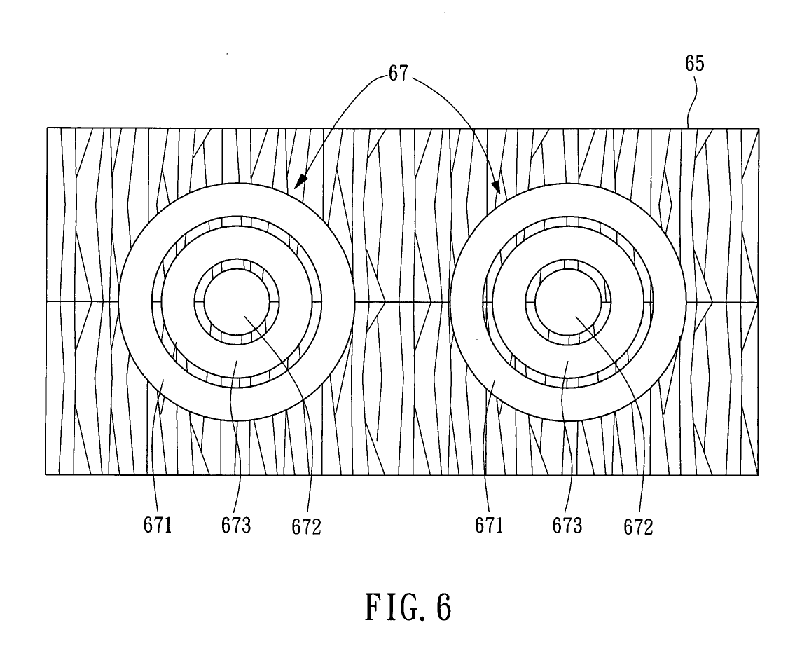

For example, please refer to FIG. 5, which is a top view of a transistor layout design used in a method for forming a poly-silicon thin-film device according to a third embodiment of the present invention. In the third embodiment, a plurality of thin-film transistors 57 are formed on a poly-silicon film 55. Each of the thin-film transistors 57 includes a channel region 573 formed from a portion of the poly-silicon film 55. At least one channel region 573 is fan-shaped. The fan-shaped channel region 573 has an equivalent parallel channel region CHL with a channel direction parallel to the grain growth direction and an equivalent perpendicular channel region CH_{H}, with a channel direction perpendicular to the grain growth direction. In practical use, the first electrode 571 and the second electrode 572 as shown in FIG. 5 form drain and source electrodes.

Please further refer to FIG. 6, which is a top view of a transistor layout design used in a method for forming a poly-silicon thin-film device according to a fourth embodiment of the present invention. In the fourth embodiment, a plurality of thin-film transistors 67 are formed on a poly-silicon film 65. Each of the thin-film transistors 67 includes a channel region 673 formed from a portion of the poly-silicon film 65. At least one channel region 673 is donut-shaped. The donut-shaped channel region 673 has an equivalent parallel channel region CH_{L} with a channel direction parallel to the grain growth direction and an equivalent perpendicular channel region CH_{H} with a channel direction perpendicular to the grain growth direction. In practical use, the first electrode 671 and the second electrode 672 as shown in FIG. 6 form the drain and source electrodes.

The poly-silicon thin-film device formed using the method disclosed in the present invention can be used as a liquid crystal display. Alternatively, the poly-silicon thin-film device can also be a driving circuit for a display or a pixel unit for a display. Similarly, the present invention is not limited thereto. Any person with ordinary skills in the art can make modifications within the scope of the present invention.

According to the above discussion, it is apparent that the present invention discloses a method for forming a poly-silicon thin-film device using a channel region layout design so as to achieve better uniformity in electrical characteristics of thin-film transistors (TFTs) employed in the p-Si thin-film device. Therefore, the present invention is novel, useful and non-obvious.

Although this invention has been disclosed and illustrated with reference to particular embodiments, the principles involved are susceptible for use in numerous other embodiments that will be apparent to persons skilled in the art. This invention is, therefore, to be limited only as indicated by the scope of the appended claims.

What is claimed is:

1. A method for forming a poly-silicon thin-film device, comprising steps of:
providing a substrate;
forming a poly-silicon film on the substrate, the poly-silicon film comprising a plurality of poly-silicon grains oriented in a grain growth direction; and
forming a plurality of thin-film transistors, each of the thin-film transistor including a channel region formed from a portion of the poly-silicon film;
wherein at least one channel region has an equivalent parallel channel region with a channel direction parallel to the grain growth direction and an equivalent perpendicular channel region with a channel direction perpendicular to the grain growth direction.

2. The method as recited in claim 1, wherein the poly-silicon film has a plurality of primary grain boundaries perpendicular to the grain growth direction and a plurality of secondary grain boundaries parallel to the grain growth direction.

3. The method as recited in claim 1, wherein the poly-silicon film is formed using sequential lateral solidification (SLS) with at least one laser irradiation.

4. The method as recited in claim 1, wherein the channel region is L-shaped.

5. The method as recited in claim 1, wherein the channel region is multi-L shaped.

6. The method as recited in claim 1, wherein the channel region is fan-shaped.

7. The method as recited in claim 1, wherein the channel region is circular-shaped.

8. The method as recited in claim 1, wherein the poly-silicon thin-film device is a liquid crystal display.

9. The method as recited in claim 1, wherein the poly-silicon thin-film device is a driving circuit for a display.

10. The method as recited in claim 1, wherein the poly-silicon thin-film device is a pixel unit for a display.
